(19) United States
(12) Patent Application Publication
(10) Pub. No.: US 2010/0032642 A1
(43) Pub. Date: Feb. 11, 2010

(54) Method of Manufacturing a Resistivity Changing Memory Cell, Resistivity Changing Memory Cell, Integrated Circuit, and Memory Module

(76) Inventors: Chanro Park, Austin, TX (US); Rainer Leuschner, Regensburg (DE)

Correspondence Address: SLATER & MATSIL, L.L.P., 17950 PRESTON ROAD, SUITE 1000, DALLAS, TX, 75252, US

(21) Appl. No.: 12/187,258

(22) Filed: Aug. 6, 2008

(51) Int. Cl. H01L 21/283; H01L 45/00

(52) U.S. Cl. 257/4; 438/652; 257/E21.159; 257/E45.002

(57) ABSTRACT

According to an embodiment, a method of manufacturing an integrated circuit including a plurality of resistivity changing memory cells is provided. The method includes: forming a stack of layers including a resistivity changing layer, a first conductive layer, a second conductive layer, and a patterned masking layer which are stacked above each other in this order; patterning the second conductive layer using the masking layer as a patterning mask; patterning the first conductive layer using the second conductive layer as a patterning mask; and patterning the resistivity changing layer using the first conductive layer as a patterning mask.

### TECHNICAL FIELD

Integrated circuits including resistivity changing memory cells are known. It is desirable to provide manufacturing methods which improve the reproducibility of integrated circuits having resistivity changing memory cells, in particular when scaling down to small feature sizes.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows a schematic view of an integrated circuit according to an embodiment;

FIG. 2 shows a schematic view of a part of the integrated circuit of FIG. 1 according to an embodiment;

FIG. 3A shows a schematic perspective view of a part of an integrated circuit using magneto-resistive memory cells;

FIG. 3B shows a schematic view of a circuit usable in conjunction with the integrated circuit shown in FIG. 1;

FIG. 4A shows a schematic cross-sectional view of a solid electrolyte memory cell set to a first memory state;

FIG. 4B shows a schematic cross-sectional view of a solid electrolyte memory cell set to a second memory state;

FIG. 5A shows a schematic cross-sectional view of a phase changing memory cell;

FIG. 5B shows a schematic drawing of an integrated circuit including resistivity changing memory cells;

FIG. 6 shows a schematic drawing of a part of an integrated circuit including resistivity changing memory cells;

FIG. 7 shows a schematic drawing of a part of an integrated circuit including resistivity changing memory cells;

FIG. 8 shows a flow chart of a method of manufacturing a resistivity changing memory cell according to an embodiment;

FIG. 9 shows a schematic cross-sectional view of a manufacturing stage of a method of manufacturing a resistivity changing memory cell according to an embodiment;

FIG. 10 shows a schematic cross-sectional view of a manufacturing stage of a method of manufacturing a resistivity changing memory cell according to an embodiment;

FIG. 11 shows a schematic cross-sectional view of a manufacturing stage of a method of manufacturing a resistivity changing memory cell according to an embodiment;

FIG. 12 shows a schematic cross-sectional view of a manufacturing stage of a method of manufacturing a resistivity changing memory cell according to an embodiment;

FIG. 13 shows a schematic cross-sectional view of a manufacturing stage of a method of manufacturing a resistivity changing memory cell according to an embodiment;

FIG. 14 shows a schematic cross-sectional view of a manufacturing stage of a method of manufacturing a resistivity changing memory cell according to an embodiment;

FIG. 15 shows a schematic cross-sectional view of a manufacturing stage of a method of manufacturing a resistivity changing memory cell according to an embodiment;

FIG. 16 shows a schematic cross-sectional view of a manufacturing stage of a method of manufacturing a resistivity changing memory cell according to an embodiment;

FIG. 17 shows a schematic cross-sectional view of a manufacturing stage of a method of manufacturing a resistivity changing memory cell according to an embodiment;

FIG. 18 shows a schematic cross-sectional view of a manufacturing stage of a method of manufacturing a resistivity changing memory cell according to an embodiment;

FIG. 19 shows a schematic cross-sectional view of a manufacturing stage of a method of manufacturing a resistivity changing memory cell according to an embodiment;

FIG. 20 shows a schematic cross-sectional view of a manufacturing stage of a method of manufacturing a resistivity changing memory cell according to an embodiment;

FIG. 21 shows a schematic cross-sectional view of a manufacturing stage of a method of manufacturing a resistivity changing memory cell according to an embodiment;

FIG. 22 shows a schematic cross-sectional view of a manufacturing stage of a method of manufacturing a resistivity changing memory cell according to an embodiment;

FIG. 23 shows a schematic cross-sectional view of a resistivity changing memory cell according to an embodiment;

FIG. 24A shows a schematic perspective view of a memory module according to an embodiment; and

FIG. 24B shows a schematic perspective view of a memory module according to an embodiment.

### DETAILED DESCRIPTION OF ILLUSTRATIVE EMBODIMENTS

As used herein the terms “connected” and “coupled” are intended to include both direct and indirect connection and coupling, respectively.

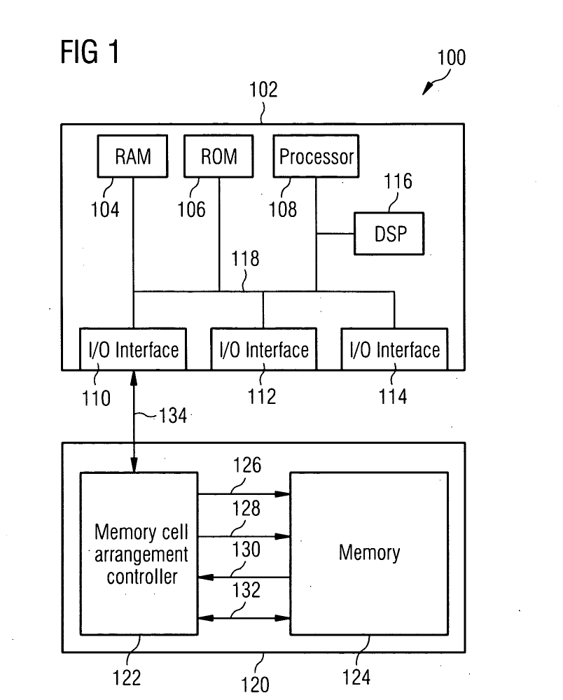

FIG. 1 shows a computer system 100 having a computer arrangement 102 and a memory cell arrangement 120 in accordance with an embodiment.

In various embodiments, the computer arrangement 102 may be configured as or may include any device having a processor, e.g., having a programmable processor such as, e.g., a microprocessor (e.g., a CISC (complex instruction set computer) microprocessor or a RISC (reduced instruction set computer) microprocessor). In various embodiments, the computer arrangement 102 may be configured as or may include a personal computer, a workstation, a laptop, a notebook, a personal digital assistant (PDA), a radio telephone (e.g., a wireless radio telephone or a mobile radio telephone), a camera (e.g., an analog camera or a digital camera), or another device having a processor (such as, e.g., a household appliance (such as, e.g., a washing machine, a dishwashing machine, etc.))

In an embodiment, the computer arrangement 102 may include one or a plurality of computer arrangement-internal random access memories (RAM) 104, e.g., one or a plurality of computer arrangement-internal dynamic random access memories (DRAM), in which, for example, data to be processed may be stored. Furthermore, the computer arrangement 102 may include one or a plurality of computer arrangement-internal read only memories (ROM) 106, in which, for example, the program code may be stored, which should be executed by a processor 108 (e.g., a processor as described above), which may also be provided in the computer arrangement 102.

Furthermore, in an embodiment, one or a plurality of input/output interfaces 110, 112, 114 (in FIG. 1, there are shown three input/output interfaces, in alternative embodiments, e.g., one, two, four, or even more than four input/output interfaces may be provided) configured to connect one or a plurality of computer arrangement-external devices (such as, e.g., additional memory, one or a plurality of communication devices, one or a plurality of additional processors) to the computer arrangement 102, may be provided in the computer arrangement 102.

The input/output interfaces 110, 112, 114 may be implemented as analog interfaces and/or as digital interfaces. The input/output interfaces 110, 112, 114 may be implemented as serial interfaces and/or as parallel interfaces. The input/output interfaces 110, 112, 114 may be implemented as one or a plurality of circuits, which implements or implement a respective communication protocol stack in its functionality in accordance with the communication protocol which is respectively used for data transmission. Each of the input/output interfaces 110, 112, 114 may be configured in accordance with any communication protocol. In an embodiment, each of the input/output interfaces 110, 112, 114 may be implemented in accordance with one of the following communication protocols:

an ad hoc communication protocol such as, e.g., Firewire or Bluetooth;

a communication protocol for a serial data transmission such as, e.g., RS-232, Universal Serial Bus (USB) (e.g., USB 1.0, USB 1.1, USB 2.0, USB 3.0);

any other communication protocol such as, e.g., Infrared Data Association (IrDA).

In an embodiment, the first input/output interface 110 is a USB interface (in alternative embodiments, the first input/output interface 110 may be configured in accordance with any other communication protocol such as, e.g., in accordance with a communication protocol which has been described above).

In an embodiment, the computer arrangement 102 optionally may include an additional digital signal processor (DSP) 116, which may be provided, e.g., for digital signal processing. Furthermore, the computer arrangement 102 may include additional communication modules (not shown) such as, e.g., one or a plurality of transmitters, one or a plurality of receivers, one or a plurality of antennas, and so on.

The computer arrangement 102 may also include additional components (not shown), which are desired or required in the respective application.

In an embodiment, some or all of the circuits or components provided in the computer arrangement 102 may be coupled with each other by means of one or a plurality of computer arrangement-internal connections 118 (for example, by means of one or a plurality of computer busses) configured to transmit data and/or control signals between the respectively coupled circuits or components.

Furthermore, as has been described above, the computer system 100, in accordance with an embodiment, may include the memory cell arrangement 120.

The memory cell arrangement 120 may in an embodiment be configured as an integrated circuit. The memory cell arrangement 120 may further be provided in a memory module having a plurality of integrated circuits, wherein at least one integrated circuit of the plurality of integrated circuits includes a memory cell arrangement 120, as will be described in more detail below. The memory module may be a stackable memory module, wherein some of the integrated circuit may be stacked one above the other. In an embodiment, the memory cell arrangement 120 is configured as a memory card.

In an embodiment, the memory cell arrangement 120 may include a memory cell arrangement controller 122 (for example, implemented by means of hard wired logic and/or by means of one or a plurality of programmable processors, e.g., by means of one or a plurality of programmable processors such as, e.g., one or a plurality of programmable microprocessors (e.g., CISC (complex instruction set computer) microprocessor(s) or RISC (reduced instruction set computer) microprocessor(s)).

The memory cell arrangement 120 may further include a memory 124 having a plurality of memory cells. The memory 124 will be described in more detail below.

In an embodiment, the memory cell arrangement controller 122 may be coupled with the memory 124 by means of various connections. Each of the connections may include one or a plurality of lines and may thus have a bus width of one or a plurality of bits. Thus, by way of example, an address bus 126 may be provided, by means of which one or a plurality of addresses of one or a plurality of memory cells may be provided by the memory cell arrangement controller 122 to the memory 124, on which an operation (e.g., an erase operation, a write operation, a read operation, an erase verify operation, or a write verify operation, etc.) should be carried out. Furthermore, a data write connection 128 may be provided, by means of which the information to be written into the respectively addressed memory cell may be supplied by the memory cell arrangement controller 122 to the memory 124. Furthermore, a data read connection 130 may be provided, by means of which the information stored in the respectively addressed memory cell may be read out of the memory 124 and may be supplied from the memory 124 to the memory cell arrangement controller 122 and via the memory cell arrangement controller 122 to the computer arrangement 102, or, alternatively, directly to the computer arrangement 102 (in which case the first input/output interface 110 would directly be connected to the memory 124). A bidirectional control/state connection 132 may be used for providing control signals from the memory cell arrangement controller 122 to the memory 124 or for supplying state signals representing the state of the memory 124 from the memory 124 to the memory cell arrangement controller 122.

In an embodiment, the memory cell arrangement controller 122 may be coupled to the first input/output interface 110 by means of a communication connection 134 (e.g., by means of a USB communication connection).

In an embodiment, the memory 124 may include one chip or a plurality of chips. Furthermore, the memory cell arrangement controller 122 may be implemented on the same chip (or die) as the components of the memory 124 or on a separate chip (or die).

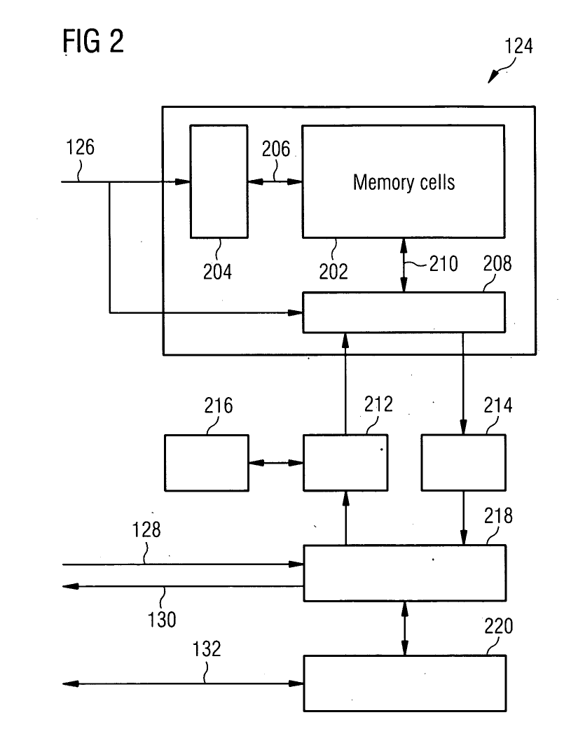

FIG. 2 shows the memory 124 of FIG. 1 in accordance with an embodiment in more detail.

In an embodiment, the memory 124 may include a memory cell field (e.g., a memory cell array) 202 having a plurality of memory cells. The memory cells may be arranged in the memory cell field 202 in the form of a matrix in rows and columns, or, alternatively, for example, in zig zag form. In other embodiments, the memory cells may be arranged within the memory cell field 202 in any other manner or architecture.

In general, each memory cell may, for example, be coupled with a first control line (e.g., a word line) and with at least one second control line (e.g., at least one bit line).

In an embodiment, in which the memory cells are arranged in the memory cell field 202 in the form of a matrix in rows and columns, a row decoder circuit 204 configured to select at least one row control line (e.g., a word line) of a plurality of row control lines 206 in the memory cell field 202 may be provided as well as a column decoder circuit 208 configured to select at least one column control line (e.g., a bit line) of a plurality of column control lines 210 in the memory cell field 202.

The memory cells at least partly include non-volatile memory cells. A “non-volatile memory cell” may be understood as a memory cell storing data even if it is not active. In an embodiment, a memory cell may be understood as being not active, e.g., if current access to the content of the memory cell is inactive. In another embodiment, a memory cell may be understood as being not active, e.g., if the power supply is inactive. Furthermore, the stored data may be refreshed on a regular timely basis, but not, as with a “volatile memory cell” every few picoseconds or nanoseconds or milliseconds, but rather in a range of hours, days, weeks or months. Alternatively, the data may not need to be refreshed at all in some designs.

In an embodiment, the memory cells may be multi-bit memory cells. As used herein the term “multi-bit” memory cell is intended to, e.g., include memory cells which are configured to store a plurality of bits by spatially separated electric charge storage regions or current conductivity regions, thereby representing a plurality of logic states.

In another embodiment, the memory cells may be multi-level memory cells. As used herein the term “multi-level” memory cell is intended to, e.g., include memory cells which are configured to store a plurality of bits by showing distinguishable voltage or current levels dependent on the amount of electric charge stored in the memory cell or the amount of electric current flowing through the memory cell, thereby representing a plurality of logic states.

In an embodiment, address signals are supplied to the row decoder circuit 204 and the column decoder circuit 208 by means of the address bus 126, which is coupled to the row decoder circuit 204 and to the column decoder circuit 208. The address signals uniquely identify at least one memory cell to be selected for an access operation (e.g., for one of the above described operations). The row decoder circuit 204 selects at least one row and thus at least one row control line 206 in accordance with the supplied address signal. Furthermore, the column decoder circuit 208 selects at least one column and thus at least one column control line 210 in accordance with the supplied address signal.

The electrical voltages that are provided in accordance with the selected operation, e.g., for reading, programming (e.g., writing) or erasing of one memory cell or of a plurality of memory cells, are applied to the selected at least one row control line 206 and to the at least one column control line 210.

In the case that each memory cell is configured in the form of a resistive memory cell having only two terminals, a first terminal of the resistive memory cell may be coupled to the row control line 206 and a second terminal of the resistive memory cell may be coupled to the column control line 210.

In the case that each memory cell is configured in the form of a field effect transistor (e.g., in the case of a charge storing memory cell), in an embodiment, the respective gate terminal is coupled to the row control line 206 and a first source/drain terminal is coupled to a first column control line 210. A second source/drain terminal may be coupled to a second column control line 210. Alternatively, with a first source/drain terminal of an adjacent memory cell, which may then, e.g., also be coupled to the same row control line 206 (this is the case, e.g., in a NAND arrangement of the memory cells in the memory cell field 202).

In an embodiment, by way of example, for reading or for programming, a single row control line 206 and a single column control line 210 are selected at the same time and are appropriately driven for reading or programming of the thus selected memory cell. In an alternative embodiment, it may be provided to respectively select a single row control line 206 and a plurality of column control lines 210 at the same time for reading or for programming, thereby allowing to read or program a plurality of memory cells at the same time.

Furthermore, in an embodiment, the memory 124 includes at least one write buffer memory 212 and at least one read buffer memory 214. The at least one write buffer memory 212 and the at least one read buffer memory 214 are coupled with the column decoder circuit 208. Depending on the type of memory cell, reference memory cells 216 may be provided for reading the memory cells.

In order to program (e.g., write) a memory cell, the data to be programmed may be received by a data register 218, which is coupled with the data write connection 128, by means of the data write connection 128, and may be buffered in the at least one write buffer memory 212 during the write operation.

In order to read a memory cell, the data read from the addressed memory cell (represented, e.g., by means of an electrical current, which flows through the addressed memory cell and the corresponding column control line 210, which may be compared with a current threshold value in order to determine the content of the memory cell, wherein the current threshold value may, e.g., be dependent from the reference memory cells 216) are, e.g., buffered in the read buffer memory 214 during the read operation. The result of the comparison and therewith the logic state of the memory cell (wherein the logic state of the memory cell represents the memory content of the memory cell) may then be stored in the data register 218 and may be provided via the data read connection 130, with which the data register 218 may be coupled.

The access operations (e.g., write operations, read operations, or erase operations) may be controlled by a memory-internal controller 220, which in turn may be controlled by the memory cell arrangement controller 122 by means of the bidirectional control/state connection 132. In an alternative embodiment, the data register 218 may directly be connected to the memory cell arrangement controller 122 by means of the bidirectional control/state connection 132 and thus directly controlled thereby. In this example, the memory-internal controller 220 may be omitted.

In an embodiment, the memory cells of the memory cell field may be grouped into memory blocks or memory sectors, which may be commonly erased in an erase operation. In an embodiment, there are so many memory cells included in a memory block or memory sector such that the same amount of data may be stored therein as compared with a conventional hard disk memory sector (e.g., 512 byte), although a memory block or memory sector may alternatively also store another amount of data.

Furthermore, other common memory components (e.g., peripheral circuits such as, e.g., charge pump circuits, etc.) may be provided in the memory 124, but they are neither shown in FIG. 1 nor FIG. 2 for reasons of clarity.

According to an embodiment, the resistivity changing memory cells which are provided in the memory cell field 202 are magneto-resistive memory cells. Thus, in the following description, a brief discussion of magneto-resistive memory cells will be given.

Magneto-resistive memory cells involve spin electronics, which combines semiconductor technology and magnetics. The spin of an electron, rather than the charge, is used to indicate the presence of a “1” or “0”.

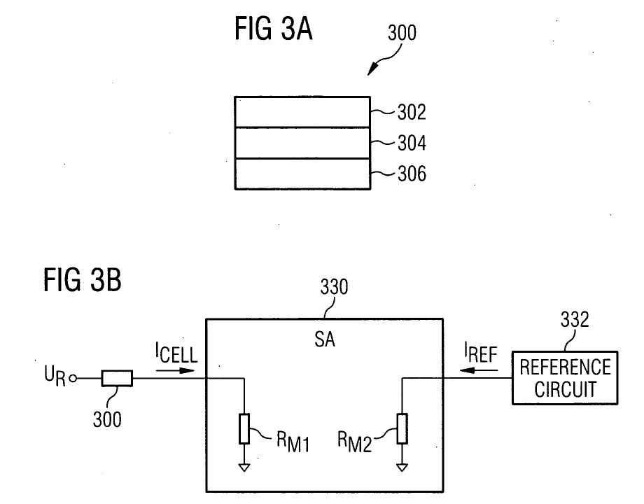

FIG. 3A illustrates a cross-sectional view of a magneto-resistive memory cell 300 including a soft layer 302, a tunnel layer 304, and a hard layer 306, for example. Soft layer 302 and hard layer 306 preferably include a plurality of magnetic metal layers, for example, eight to twelve layers of materials such as PtMn, CoFe, Ru, and NiFe, as examples. A logic state is represented by the magnetizations of the soft layer 302 and the hard layer 306.

In order to read the logic state stored in the magneto-resistive memory cell 300 a schematic such as the one shown in FIG. 3B, including a sense amplifier (SA) 330, may be used. A reference voltage U_{R} is applied to one end of the memory cell 300. The other end of the memory cell 300 is coupled to a measurement resistor Rₘ₁. The other end of the measurement resistor Rₘ₁ is coupled to ground. The current running through the memory cell 300 is equal to current I_{cell}. A reference circuit 332 supplies a reference current I_{ref} that is run into measurement resistor Rₘ₂. The other end of the measurement resistor Rₘ₂ is coupled to ground, as shown.

According to an embodiment, the resistivity changing memory cells which are provided in the memory cell field 202 are programmable metallization cells (PMCs) like conductive bridging random access memory cells (CBRAM cells). Thus, in the following description, a brief discussion of CBRAM cells will be given.

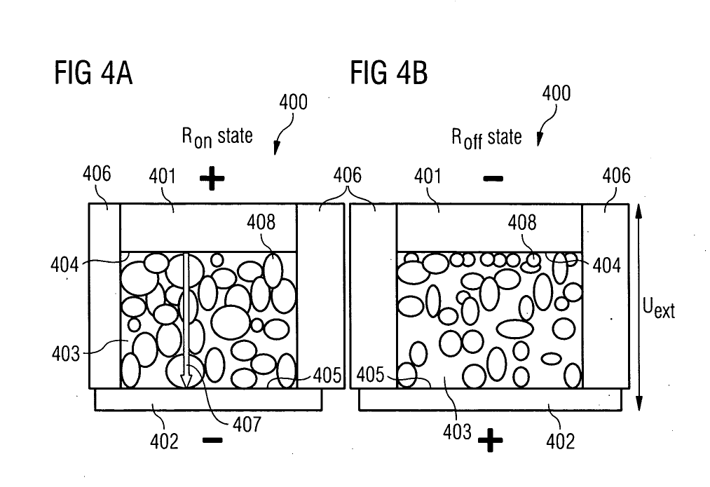

As shown in FIG. 4A, a CBRAM cell 400 includes a first electrode 401, a second electrode 402, and a solid electrolyte block (in the following also referred to as ion conductor block) 403 which includes the active material and which is sandwiched between the first electrode 401 and the second electrode 402. This solid electrolyte block 403 can also be shared between a plurality of memory cells (not shown here). The first electrode 401 contacts a first surface 404 of the ion conductor block 403, the second electrode 402 contacts a second surface 405 of the ion conductor block 403. The ion conductor block 403 is isolated against its environment by an isolation structure 406. The first surface 404 usually is the top surface, the second surface 405 the bottom surface of the ion conductor 403. In the same way, the first electrode 401 generally is the top electrode, and the second electrode 402 the bottom electrode of the CBRAM cell. One of the first electrode 401 and the second electrode 402 is a reactive electrode, the other one an inert electrode. Here, the first electrode 401 is the reactive electrode, and the second electrode 402 is the inert electrode. In this example, the first electrode 401 includes silver (Ag), the ion conductor block 403 includes silver-doped chalcogenide material, the second electrode 402 includes tungsten (W), and the isolation structure 406 includes SiO₂ or Si₃N₄. The present invention is however not restricted to these materials. For example, the first electrode 401 may alternatively or additionally include copper (Cu) or zinc (Zn), and the ion conductor block 403 may alternatively or additionally include copper-doped chalcogenide material. Further, the second electrode 402 may alternatively or additionally include nickel (Ni) or platinum (Pt), iridium (Ir), rhenium (Re), tantalum (Ta), titanium (Ti), ruthenium (Ru), molybdenum (Mo), vanadium (V), conductive oxides, silicides, and nitrides of the aforementioned materials, and can also include alloys of the aforementioned materials. The thickness of the ion conductor 403 may, for example, range between about 5 nm and about 500 nm. The thickness of the first electrode 401 may, for example, range between about 10 nm and about 100 nm. The thickness of the second electrode 402 may, for example, range between about 5 nm and about 500 nm, between about 15 nm to about 150 nm, or between about 25 nm and about 100 nm. It is to be understood that the present invention is not restricted to the above-mentioned materials and thicknesses.

In the context of this description, chalcogenide material (ion conductor) is to be understood, for example, as any compound containing oxygen, sulphur, selenium, germanium and/or tellurium. In accordance with one embodiment of the invention, the ion conducting material is, for example, a compound, which is made of a chalcogenide and at least one metal of the group I or group II of the periodic system, for example, arsenic-trisulfide-silver. Alternatively, the chalcogenide material contains germanium-sulfide (GeSₓ), germanium-selenide (GeSeₓ), tungsten oxide (WOₓ), copper sulfide (CuSₓ) or the like. The ion conducting material may be a solid state electrolyte. Furthermore, the ion conducting material can be made of a chalcogenide material containing metal ions, wherein the metal ions can be made of a metal, which is selected from a group consisting of silver, copper and zinc or of a combination or an alloy of these metals.

If a voltage as indicated in FIG. 4A is applied across the ion conductor block 403, a redox reaction is initiated which drives Ag⁺ ions out of the first electrode 401 into the ion conductor block 403 where they are reduced to Ag, thereby forming Ag rich clusters 408 within the ion conductor block 403. If the voltage applied across the ion conductor block 403 is applied for an enhanced period of time, the size and the number of Ag rich clusters within the ion conductor block 403 is increased to such an extent that a conductive bridge 407 between the first electrode 401 and the second electrode 402 is formed. In case that a voltage is applied across the ion conductor 403 as shown in FIG. 4B (inverse voltage compared to the voltage applied in FIG. 4A), a redox reaction is initiated which drives Ag⁺ ions out of the ion conductor block 403 into the first electrode 401 where they are reduced to Ag. As a consequence, the size and the number of Ag rich clusters within the ion conductor block 403 is reduced, thereby erasing the conductive bridge 407. After having applied the voltage/inverse voltage, the memory cell 400 remains within the corresponding defined switching state even if the voltage/inverse voltage has been removed.

In order to determine the current memory status of a CBRAM cell, for example, a sensing current is routed through the CBRAM cell. The sensing current experiences a high resistance in case no conductive bridge 407 exists within the CBRAM cell, and experiences a low resistance in case a conductive bridge 407 exists within the CBRAM cell. A high resistance may, for example, represent “0”, whereas a low resistance represents “1”, or vice versa. The memory status detection may also be carried out using sensing voltages. Alternatively, a sensing voltage may be used in order to determine the current memory status of a CBRAM cell.

According to an embodiment, the resistivity changing memory cells which are provided in the memory cell field 202 are phase changing cells like phase changing random access memory cells (PCRAM cells). Thus, in the following description, a brief discussion of PCRAM cells will be given.

According to an embodiment, the resistivity changing memory cells are phase change memory cells that include a phase change material. The phase change material can be switched between at least two different crystallization states (i.e., the phase change material may adopt at least two different degrees of crystallization), wherein each crystallization state may be used to represent a memory state. When the number of possible crystallization states is two, the crystallization state having a high degree of crystallization is also referred to as “crystalline state”, whereas the crystallization state having a low degree of crystallization is also referred to as an “amorphous state”. Different crystallization states can be distinguished from each other by their differing electrical properties, and in particular by their different resistances. For example, a crystallization state having a high degree of crystallization (ordered atomic structure) generally has a lower resistance than a crystallization state having a low degree of crystallization (disordered atomic structure). For sake of simplicity, it will be assumed in the following that the phase change material can adopt two crystallization states (an “amorphous state” and a “crystalline state”), however it will be understood that additional intermediate states may also be used.

Phase change memory cells may change from the amorphous state to the crystalline state (and vice versa) due to temperature changes of the phase change material. These temperature changes may be caused using different approaches. For example, a current may be driven through the phase change material (or a voltage may be applied across the phase change material). Alternatively, a current or a voltage may be fed to a resistive heater which is disposed adjacent to the phase change material. To determine the memory state of a resistivity changing memory cell, a sensing current may routed through the phase change material (or a sensing voltage may be applied across the phase change material), thereby sensing its resistivity which represents the memory state of the memory cell.

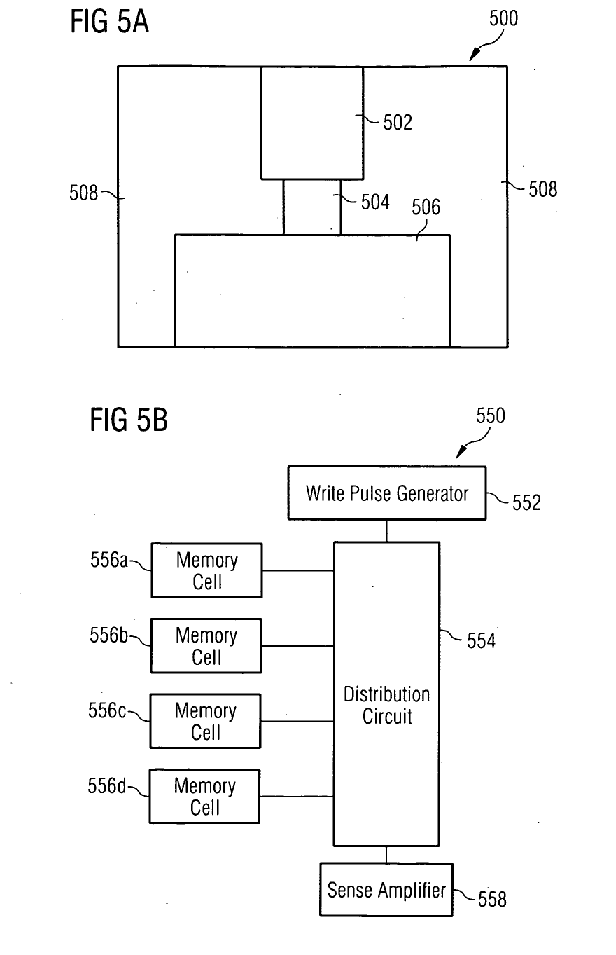

FIG. 5A illustrates a cross-sectional view of an exemplary phase change memory cell 500 (active-in-via type). The phase change memory cell 500 includes a first electrode 502, a phase change material 504, a second electrode 506, and an insulating material 508. The phase change material 504 is laterally enclosed by the insulating material 508. To use the phase change memory cell, a selection device (not shown), such as a transistor, a diode, or another active device, may be coupled to the first electrode 502 or to the second electrode 506 to control the application of a current or a voltage to the phase change material 504 via the first electrode 502 and/or the second electrode 506. To set the phase change material 504 to the crystalline state, a current pulse and/or voltage pulse may be applied to the phase change material 504, wherein the pulse parameters are chosen such that the phase change material 504 is heated above its crystallization temperature, generally keeping the temperature below the melting temperature of the phase change material 504. To set the phase change material 504 to the amorphous state, a current pulse and/or voltage pulse may be applied to the phase change material 504, wherein the pulse parameters are chosen such that the phase change material 504 is briefly heated above its melting temperature, and is quickly cooled.

The phase change material 504 may include a variety of materials. According to one embodiment, the phase change material 504 may include or consist of a chalcogenide alloy that includes one or more elements from group VI of the periodic table. According to another embodiment, the phase change material 504 may include or consist of a chalcogenide compound material, such as GeSbTe, SbTe, GeTe or AgInSbTe. According to a further embodiment, the phase change material 504 may include or consist of chalcogen free material, such as GeSb, GaSb, InSb, or GeGaInSb. According to still another embodiment, the phase change material 504 may include or consist of any suitable material including one or more of the elements Ge, Sb, Te, Ga, Bi, Pb, Sn, Si, P, O, As, In, Se, and S.

According to one embodiment, at least one of the first electrode 502 and the second electrode 506 may include or consist of Ti, V, Cr, Zr, Nb, Mo, Hf, Ta, W, or mixtures or alloys thereof. According to another embodiment, at least one of the first electrode 502 and the second electrode 506 may include or consist of Ti, V, Cr, Zr, Nb, Mo, Hf, Ta, W and one or more elements selected from the group consisting of B, C, N, O, Al, Si, P, S, and/or mixtures and alloys thereof Examples of such materials include TiCN, TiAlN, TiSiN, W—Al₂O₃ and Cr—Al₂O₃.

FIG. 5B illustrates a block diagram of a memory device 550 including a write pulse generator 552, a distribution circuit 554, phase change memory cells 556a, 556b, 556c, 556d (for example, phase change memory cell 500 as shown in FIG. 5A), and a sense amplifier 558. According to one embodiment, the write pulse generator 552 generates current pulses or voltage pulses that are supplied to the phase change memory cells 556a, 556b, 556c, 556d via the distribution circuit 554, thereby programming the memory states of the phase change memory cells 556a, 556b, 556c, 556d. According to one embodiment, the distribution circuit 554 includes a plurality of transistors that supply direct current pulses or direct voltage pulses to the phase change memory cells 556a, 556b, 556c, 556d or to heaters being disposed adjacent to the phase change memory cells 556a, 556b, 556c, 556d.

As already indicated, the phase change material of the phase change memory cells 556a, 556b, 556c, 556d may be changed from the amorphous state to the crystalline state (or vice versa) under the influence of a temperature change. More generally, the phase change material may be changed from a first degree of crystallization to a second degree of crystallization (or vice versa) under the influence of a temperature change. For example, a bit value “0” may be assigned to the first (low) degree of crystallization, and a bit value “1” may be assigned to the second (high) degree of crystallization. Since different degrees of crystallization imply different electrical resistances, the sense amplifier 558 is capable of determining the memory state of one of the phase change memory cells 556a, 556b, 556c, or 556d in dependence on the resistance of the phase change material.

To achieve high memory densities, the phase change memory cells 556a, 556b, 556c, 556d may be capable of storing multiple bits of data, i.e., the phase change material may be programmed to more than two resistance values. For example, if a phase change memory cell 556a, 556b, 556c, 556d is programmed to one of three possible resistance levels, 1.5 bits of data per memory cell can be stored. If the phase change memory cell is programmed to one of four possible resistance levels, two bits of data per memory cell can be stored, and so on.

The embodiment shown in FIG. 5B may also be applied in a similar manner to other types of resistivity changing memory cells like programmable metallization cells (PMCs), magneto-resistive memory cells (e.g., MRAMs), organic memory cells (e.g., ORAMs), or transition metal oxide memory cells (TMOs).

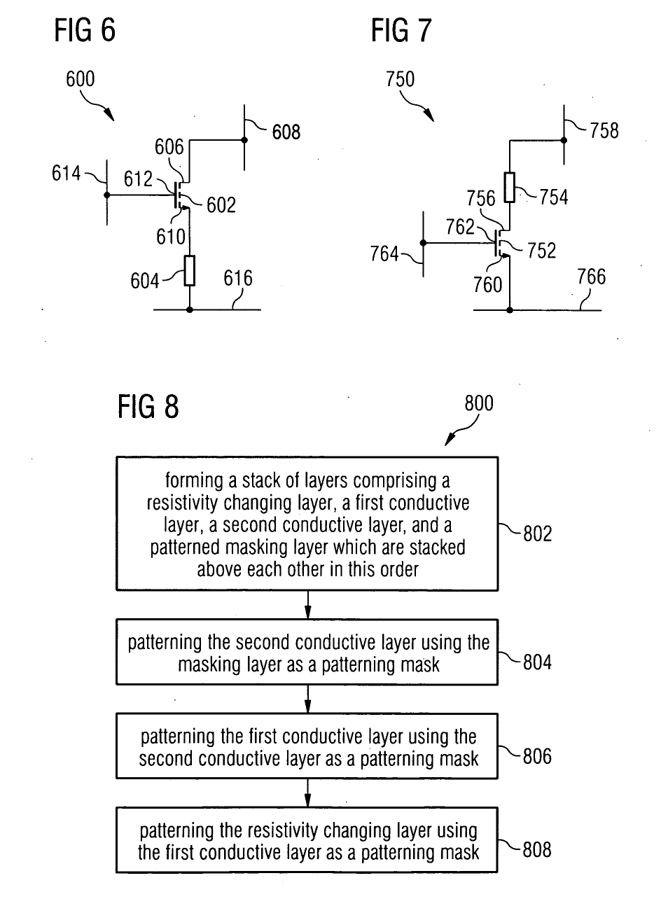

Resistivity changing memory cells, such as the phase change memory cells described above, may be used together with a transistor, diode, or other active component for selecting the memory cell. FIG. 6 shows a schematic representation of such a memory cell that uses a resistivity changing memory element. The memory cell 600 includes a select transistor 602 and a resistivity changing memory element 604. The select transistor 602 includes a source 606 that is connected to a bit line 608, a drain 610 that is connected to the memory element 604, and a gate 612 that is connected to a word line 614. The resistivity changing memory element 604 also is connected to a common line 616, which may be connected to ground, or to other circuitry, such as circuitry (not shown) for determining the resistance of the memory cell 600, for use in reading. Alternatively, in some configurations, circuitry (not shown) for determining the state of the memory cell 600 during reading may be connected to the bit line 608. It should be noted that as used herein the terms connected and coupled are intended to include both direct and indirect connection and coupling, respectively.

To write to the memory cell 600, the word line 614 is used to select the memory cell 600, and a current (or voltage) pulse on the bit line 608 is applied to the resistivity changing memory element 604, changing the resistance of the resistivity changing memory element 604. Similarly, when reading the memory cell 600, the word line 614 is used to select the cell 600, and the bit line 608 is used to apply a reading voltage (or current) across the resistivity changing memory element 604 to measure the resistance of the resistivity changing memory element 604.

The memory cell 600 may be referred to as a 1T1J cell, because it uses one transistor, and one memory junction (the resistivity changing memory element 604). Typically, a memory device will include an array of many such cells. It will be understood that other configurations for a 1T1J memory cell, or configurations other than a 1T1J configuration may be used with a resistivity changing memory element. For example, in FIG. 7, an alternative arrangement for a 1T1J memory cell 750 is shown, in which a select transistor 752 and a resistivity changing memory element 754 have been repositioned with respect to the configuration shown in FIG. 6. In this alternative configuration, the resistivity changing memory element 754 is connected to a bit line 758, and to a source 756 of the select transistor 752. A drain 760 of the select transistor 752 is connected to a common line 766, which may be connected to ground, or to other circuitry (not shown), as discussed above. A gate 762 of the select transistor 752 is controlled by a word line 764.

In all types of memory cells described above, one of the electrodes and/or contacts of the memory cell may respectively include a first conductive layer and a second conductive layer manufactured as explained in the following.

FIG. 8 shows a method 800 of manufacturing a resistivity changing memory cell according to an embodiment. At 802, a stack of layers is formed including a resistivity changing layer, a first conductive layer, a second conductive layer, and a patterned masking layer which are stacked above each other in this order. At 804, the second conductive layer is patterned using the masking layer as a patterning mask. At 806, the first conductive layer is patterned using the second conductive layer as a patterning mask. At 808, the resistivity changing layer is patterned using the first conductive layer as a patterning mask.

According to an embodiment, the first conductive layer is patterned at 806 using selective etching.

According to an embodiment, the selective etching is carried out using a non-corrosive or low-corrosive etching substance.

According to an embodiment, the non/low-corrosive etching substance used during the etching process is a fluorine plasma. The fluorine plasma may, for example, be a plasma based on Ar and CF₄, Ar and CHF₃, or Ar and SF₆.

According to an embodiment, the thickness of the first conductive layer ranges between about 50 nm and about 200 nm. Good results are achieved if the thickness of the first conductive layer ranges between about 80 nm and about 150 nm.

According to an embodiment, the patterned masking layer is formed by a patterning process including: providing a photoresist layer on the masking layer; patterning the photoresist layer using a light exposure process; and patterning the masking layer using the photoresist layer as a patterning mask.

According to an embodiment, the masking layer includes or consists of a dielectric material. According to an embodiment, the masking layer includes or consists of oxide like SiO₂. Alternatively, the masking layer may include or consist of Si₃N₄ or a-C:H (amorphous hydrocarbon, also called diamond like carbon (DLC)).

According to an embodiment, the thickness of the masking layer ranges from about 50 nm to about 200 nm.

According to an embodiment, the masking layer is patterned using a fluorine containing plasma (in particular, suitable if the masking layer includes or consists of SiO₂ or Si₃N₄). According to an embodiment, the masking layer is patterned using a O₂ containing plasma (in particular, suitable if the masking layer includes or consists of a-C:H).

According to an embodiment, the first conductive layer includes or consists of TaN or WN, or a combination thereof.

According to an embodiment, the second conductive layer includes or consists of NiFe, Ni, Pt, Pd, Cr, or Ru, or a combination thereof.

According to an embodiment, the second conductive layer is patterned using a corrosive chlorine containing plasma. The chlorine plasma may, for example, be a plasma based on Ar and BCl, or Ar and Cl₂ (in particular, suitable if the second conductive layer includes or consists of NiFe, Ni, Pt, Pd and Cr). Alternatively, the second conductive layer may, for example, be patterned using a plasma based on O₂ and CF₄ (in particular suitable if the second conductive layer includes or consists of Ru).

According to an embodiment, a ratio: (thickness of the first conductive layer/thickness of second conductive layer) ranges between about 15/1 and about 30/1. That is, if the thickness of the first conductive layer is 100 nm, for example, the thickness of the second conductive layer would range between 3.5 nm and 7 nm. Good results have, for example, been shown using a thickness of the second conductive layer of about 5 nm.

According to an embodiment, the thickness of the first conductive layer is about 1000 A (Angstrom), and the thickness of the second conductive layer is about 70 A.

According to an embodiment, the thickness of the resistivity changing layer is about 100 nm.

According to an embodiment, the patterned first conductive layer and the patterned second conductive layer obtained at 804 and 806 together form a memory cell contact, a memory cell electrode, or a composite structure including a memory cell contact and a memory cell electrode.

According to an embodiment, the memory cell manufactured is a magneto-resistive memory cell, wherein the resistivity changing layer is a magneto-resistive layer.

According to an embodiment, the memory cell is a phase changing memory cell, and the resistivity changing layer is phase changing layer.

According to an embodiment, the memory cell is a programmable metallization cell, and the resistivity changing layer is a programmable metallization layer.

According to an embodiment, the memory cell is a carbon memory cell and the resistivity changing layer is a carbon layer.

One effect of embodiments of the manufacturing method according to the embodiment of the present invention is that it is possible to use a non-corrosive etching substance in order to pattern the first conductive layer. The use of a non-corrosive etching substance for patterning the first conductive layer is possible since the materials of the first conductive layer and the second conductive layer can be chosen such that a selective etching process having a good selective etching rate can be carried out when patterning the first conductive layer using the second conductive layer as a patterning mask. In contrast, if a patterned photoresist layer was used as a patterning mask for patterning the first conductive layer, the selective etching rate would be lower. As a consequence, the first conductive layer would be patterned with decreased patterning precision. In this way, the composite structure of the first conductive layer and the second conductive layer serves as a hard mask for patterning the resistivity changing layer. Since the bottom part of this hard mask is formed using the upper part of the hard mask as a patterning mask, the precision of the hard mask is high even if non-corrosive etching substances are used for the formation thereof. On the other hand, the use of a non-corrosive etching substance ensures that no chemical reaction will take place when exposing the top surface of the resistivity changing layer. Thus, the precision of the patterning of the resistivity changing layer can be increased. If a photoresist layer was used as a patterning mask for patterning the whole hard mask, then an etching substance would have to be used having a high selective etching rate in order to precisely pattern the hard mask. However, such an etching substance would be corrosive, thereby causing corrosion damage of the resistivity changing layer when exposing the top surface of the resistivity changing layer.

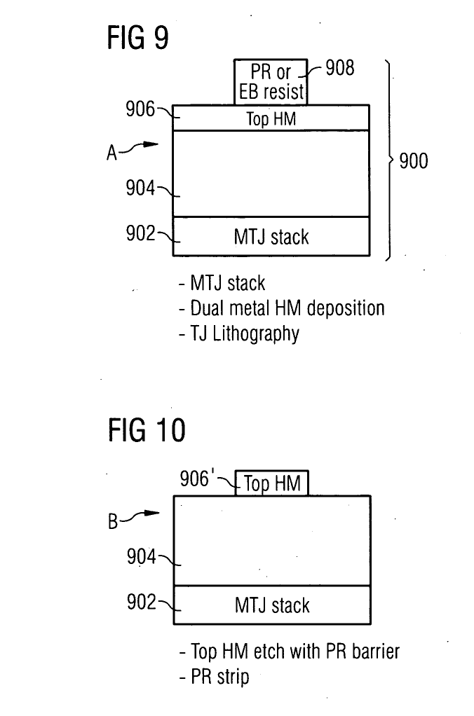

In the following description, making reference to FIGS. 9 to 12, a method of manufacturing a resistivity changing memory cell according to an embodiment will be explained.

FIG. 9 shows a manufacturing stage A obtained after having carried out the following processes: Forming a stack of layers 900 including a resistivity changing layer 902, a first conductive layer 904, a second conductive layer 906, and a patterned masking layer 908 which are stacked above each other in this order.

Here, it is assumed that the resistivity changing layer 902 is a magneto-resistive layer. However, the present invention is not restricted thereto. The resistivity changing layer 902 may, for example, also be a phase changing layer, a carbon layer, or a solid electrolyte layer. Further, the resistivity changing layer 902 may also be replaced by a stack of layers including a resistivity changing layer (e.g., a magnetic tunneling junction stack). According to an embodiment, the material of the first conductive layer 904 is different from the material of the second conductive layer 906. In this way, it is possible to selectively pattern the second conductive layer 906 without patterning the first conductive layer 904. The first conductive layer 904 may, for example, include or consist TaN or WN, the second conductive layer 906 may, for example, include or consist of NiFe, Ni, Pt, Pd, Cr, or Ru. The first conductive layer 904 and the second conductive layer 906 together form a conductive hard mask. The masking layer 908 may, for example, include or consist of photoresist material or EB (electron beam) resist material.

According to an embodiment, the patterned masking layer 908 may, for example, be provided as follows: providing a continuous resist layer on the top surface of the second conductive layer 906, and patterning the continuous resist layer using a light exposure process (lithographic process).

FIG. 10 shows a manufacturing stage B obtained after having selectively patterned the second conductive layer 906 using the patterned masking layer 908 as a patterning mask, thereby obtaining a conductive layer 906′. Further, after having patterned the second conductive layer 906, the masking layer 908 has been removed (using, for example, a strip process). The patterning of the second conductive layer 906 may, for example, be carried out using a selective etching substance which only etches the material of the second conductive layer 906, however does not etch the material of the first conductive layer 904. The second conductive layer 906 may, for example, be patterned using argon (Ar) sputtering.

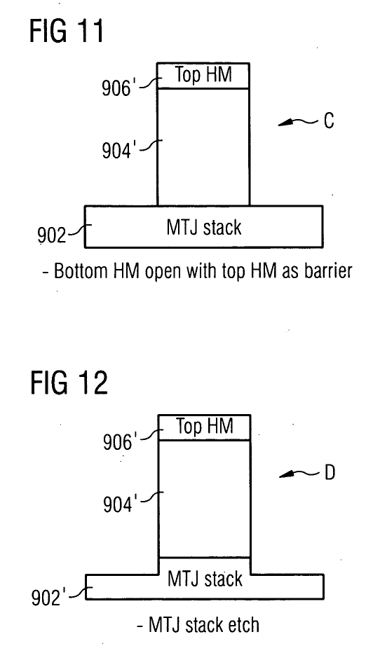

FIG. 11 shows a manufacturing stage C obtained after having patterned the first conductive layer 904 using the conductive layer 906′ as a patterning mask, thereby obtaining a conductive layer 904′. In order to pattern the first conductive layer 904, a selective etching substance may, for example, be used which has non-corrosive or low corrosive etching properties with respect to the resistivity changing layer 902 (or with respect to a stack of layers replacing the resistivity changing layer 902), i.e., which does not cause corrosion effects of the resistivity changing layer 902. For example, a fluorine plasma may be used in order to etch the first conductive layer 904. The fluorine plasma may, for example, be a plasma based on Ar and CF₄, Ar and CHF₃, or Ar and SF₆.

FIG. 12 shows a manufacturing stage D obtained after having patterned the resistivity changing layer 902 (a stack of layers replacing the resistivity changing layer 902) using the conductive layer 904′ as a patterning mask. The patterning of the resistivity changing layer 902 may, for example, be carried out using an argon plasma (pure sputtering) or an Ar/CF₄ plasma or an Ar/CHF₃ plasma, eventually followed by a water plasma or an in-situ water rinsing in order to remove the fluorine.

In the following description, making reference to FIGS. 13 to 17, a method of manufacturing a resistivity changing memory cell according to an embodiment will be explained.

FIG. 13 shows a manufacturing stage E obtained after stack of layers 900′ including a resistivity changing layer 902 (which may be replaced by a stack of layers including a resistivity changing layer), a first conductive layer 904, a second conductive layer 906, a masking layer 908, and a patterned resist layer 910 have been stacked above each other in this order. The masking layer 908 may, for example, include or consist of dielectric material like oxide material. All other layers 902, 904, 906, and 910 may include or consist of the same materials as the corresponding layers discussed in conjunction with FIG. 9.

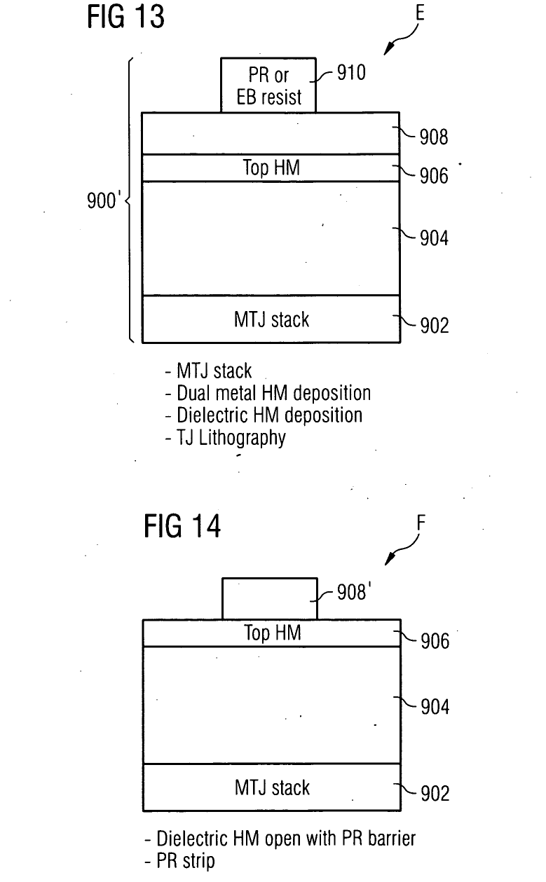

FIG. 14 shows a manufacturing stage F obtained after having patterned the masking layer 908 using the patterned resist layer 910 as a patterning mask, thereby obtaining a masking layer 908′. Further, after having patterned the masking layer 908, the resist layer 910 has been removed (using, for example, a strip process). The masking layer 908 may, for example, be patterned using a fluorine containing plasma (in particular suitable if the masking layer 908 includes or consists of SiO₂ or Si₃N₄). According to an embodiment, the masking layer 908 is patterned using an O₂ containing plasma (in particular, suitable if the masking layer 908 includes or consists of a-C:H).

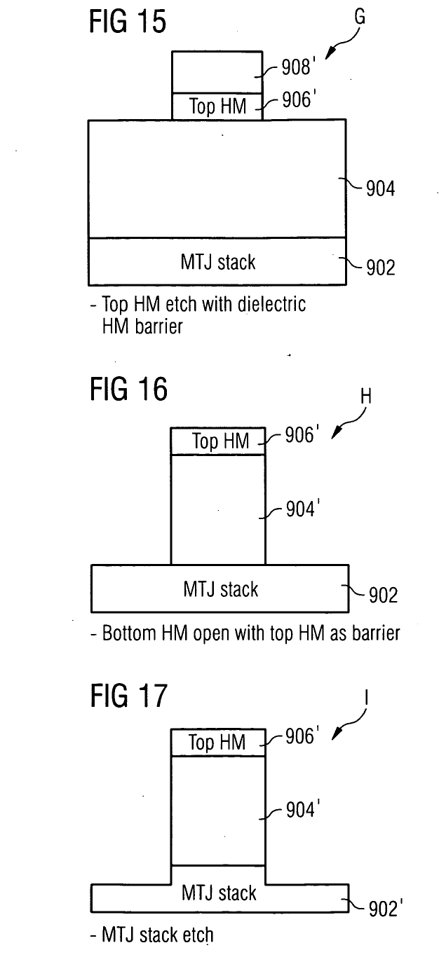

FIG. 15 shows a manufacturing stage G obtained after having patterned the second conductive layer 906 using the masking layer 908′ as a patterning mask, thereby obtaining a conductive layer 906′. The patterning of the second conductive layer 906 may, for example, be carried out using a corrosive plasma like a chlorine containing plasma. The chlorine containing plasma may, for example, be based on Ar and BCl, or Ar and Cl₂ (in particular suitable if the second conductive layer 906 includes or consists of NiFe, Ni, Pt, Pd and Cr). Alternatively, the second conductive layer 906 may, for example, be patterned using a plasma based on O₂ and CF₄ (in particular, suitable if the second conductive layer 906 includes or consists of Ru).

FIG. 16 shows a manufacturing stage H obtained after having patterned the first conductive layer 904 using the conductive layer 906′ as a patterning mask, thereby obtaining a conductive layer 904′. The patterning of the first conductive layer 904 may be carried out in the same way as discussed in conjunction with FIG. 11.

FIG. 17 shows a manufacturing stage I obtained after having patterned the resistivity changing layer 902 using the conductive layer 904′ as a patterning mask, thereby obtaining a resistivity changing layer 902′. The patterning of the resistivity changing layer 902 may be carried out in the same way as discussed in conjunction with FIG. 12.

According to an embodiment, the ratio: (thickness of the first conductive layer 904/thickness of the second conductive layer 906) ranges between about 15/1 and about 30/1.

According to an embodiment, the thickness of the resistivity changing layer 902 is about 100 nm. According to an embodiment, the thickness of the second conductive layer 906 is about 70 A. According to an embodiment, the thickness of the first conductive layer 904 ranges between about 50 nm and about 200 nm. Good results are achieved if the thickness of the first conductive layer 904 ranges between about 80 nm and about 150 nm, e.g., 1000 A.

The conductive layer 904′ and the conductive layer 906′ together form a conductive element which may be used as a top electrode/conductive via for contacting the patterned part of the resistivity changing layer 902. In this way, the hard mask (layers 904′, 906′) is both used as a patterning mask and later on as a contacting element.

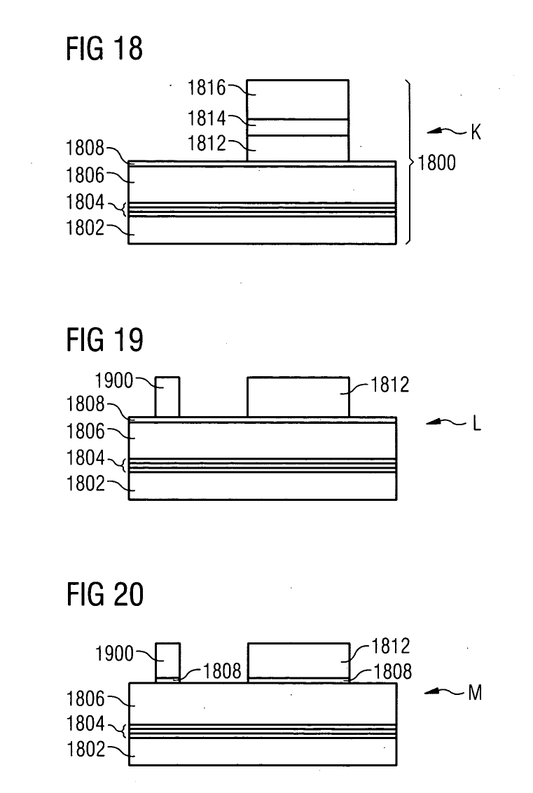

In the following description, making reference to FIGS. 18 to 22, a method of manufacturing a resistivity changing memory cell according to an embodiment will be explained.

FIG. 18 shows a manufacturing stage K obtained after having provided a stack of layers 1800 including a substrate layer 1802, a resistivity changing layer 1804 (which may be replaced by a stack of layers including a resistivity changing layer), a first conductive layer 1806, a second conductive layer 1808, a dielectric layer (e.g., oxide layer) 1812, an anti-reflective coating layer 1814, and a photoresist layer 1816 which are stacked above each other in this order. Further, the stack of layers 1800 has been patterned down to the top surface of the second conductive layer 1808. This patterning process may be carried out as follows: the photoresist layer 1816 is patterned by exposure to light; then, the anti-reflective coating layer 1814 as well as the dielectric layer 1812 are patterned using an etching substance.

FIG. 19 shows a manufacturing stage L obtained after having removed the photoresist layer 1816. Then, a second photoresist layer is formed and patterned, thereby obtaining a patterned photoresist layer 1900. After this, the anti-reflective coating layer 1814 is removed.

FIG. 20 shows a manufacturing stage M obtained after having used the dielectric layer 1812 together with the patterned photoresist layer 1900 as a patterning mask for patterning the second conductive layer 1808 down to the top surface of the first conductive layer 1806. One effect of forming different parts of one single mask (the patterned dielectric layer 1812 constitutes a first part of the mask, the patterned photoresist layer 1900 constitutes a second part of the mask) by different processes is that the accuracy of the different parts of the mask can be improved since more space (which can be used for correction structures) is available on optical masks used to generate the single mask (two optical masks are used here, one for each part of the single mask). That is, OPC (optical proximity correction) techniques or SRF (sub resolution features) techniques can be applied, for example.

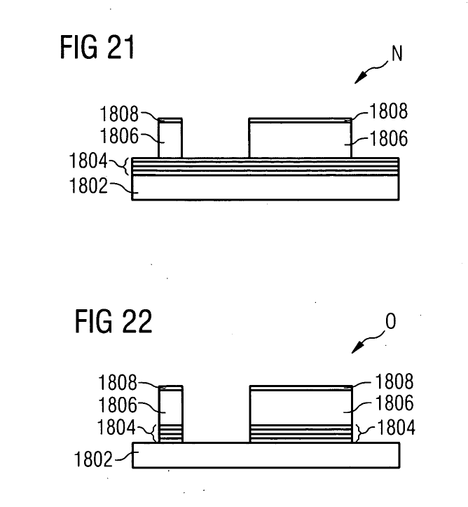

FIG. 21 shows a manufacturing stage N obtained after having removed the patterned photoresist layer 1900 and the dielectric layer 1812, and after having patterned the first conductive layer 1806 down to the top surface of the resistivity changing layer 1804.

FIG. 22 shows a manufacturing stage O obtained after having patterned the resistivity changing layer 1804 (or a stack of layers like a MTJ tunneling junction stack) down to the top surface of the substrate layer 1802. The thickness of the oxide layer 1812 may, for example, be about 800 A.

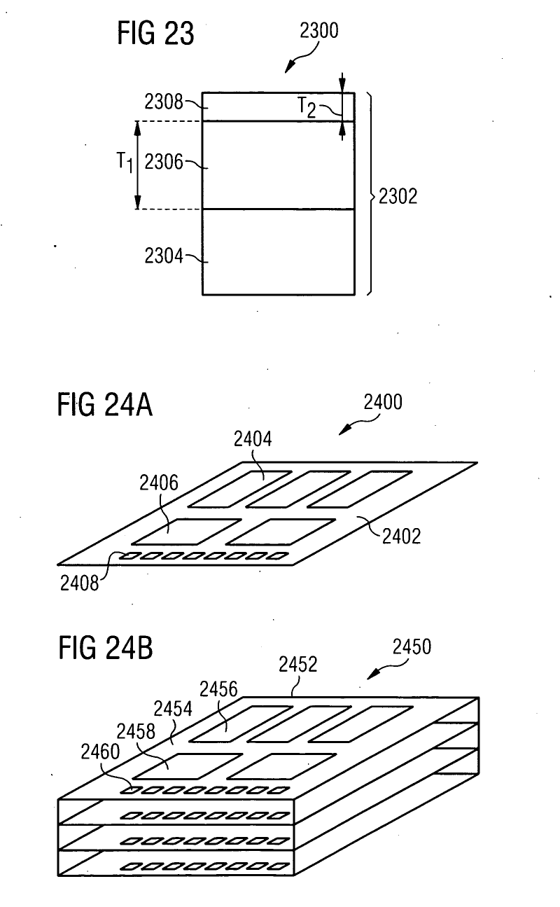

FIG. 23 shows a resistivity changing memory cell 2300 according to an embodiment. A memory cell 2300 includes a stack of layers 2302 including a resistivity changing layer 2304, a first conductive layer 2306, and a second conductive layer 2308 which are stacked above each other in this order. The first conductive layer 2306 and the second conductive layer 2308 together form a contact of the memory cell 2300 or an electrode of the memory cell 2300, or a composite structure of the memory cell 2300 including a memory cell contact and a memory cell electrode. The ratio: (thickness T1 of the first conductive layer/thickness T2 of the second conductive layer) may range between about 15/1 and about 30/1.

According to an embodiment, the materials of the first conductive layer 2306 and the second conductive layer 2308 are chosen such that the material of the first conductive layer 2306 is selectively etchable with respect to the material of the second conductive layer 2308.

According to an embodiment, an integrated circuit is provided including a plurality of resistivity changing memory cells according to embodiments of the present invention, for example, a plurality of resistivity changing memory cells 2300.

As shown in FIGS. 24A and 24B, in some embodiments, memory cells such as those described herein may be used in modules. In FIG. 24A, a memory module 2400 is shown, on which one or more integrated circuits 2404 are arranged on a substrate 2402. The integrated circuits 2404 may include numerous memory cells in accordance with an embodiment of the invention. The memory module 2400 may also include one or more electronic devices 2406, which may include memory, processing circuitry, control circuitry, addressing circuitry, bus interconnection circuitry, or other circuitry or electronic devices that may be combined on a module with a memory device, such as the integrated circuits 2404. Additionally, the memory module 2400 includes multiple electrical connections 2408, which may be used to connect the memory module 2400 to other electronic components, including other modules.

As shown in FIG. 24B, in some embodiments, these modules may be stackable, to form a stack 2450. For example, a stackable memory module 2452 may contain one or more integrated circuits 2456, arranged on a stackable substrate 2454. The integrated circuits 2456 contain memory cells in accordance with an embodiment of the invention. The stackable memory module 2452 may also include one or more electronic devices 2458, which may include memory, processing circuitry, control circuitry, addressing circuitry, bus interconnection circuitry, or other circuitry or electronic devices that may be combined on a module with a memory device, such as the integrated circuits 2456. Electrical connections 2460 are used to connect the stackable memory module 2452 with other modules in the stack 2450, or with other electronic devices. Other modules in the stack 2450 may include additional stackable memory modules, similar to the stackable memory module 2452 described above, or other types of stackable modules, such as stackable processing modules, control modules, communication modules, or other modules containing electronic components.

In the following description, further exemplary embodiments of the present invention will be explained.

As the magnetic tunneling junctions (MTJs) size gets smaller than about 100 nm, it is necessary to use very thin photoresist (PR) layers to define MTJs with optical lithography. Alternatively, in case that e-beam lithography is used to define small MTJs, it is necessary to use very thin e-beam resist layers. If a metal hard mask is also used as a top electrode, the hard mask should have a certain thickness in order to meet interconnection purpose requirements. Reactive ion etching (RIE) patterning of a thick metal mask using thin photoresist layers requires a good etch rate selectivity. The etch rate selectivity is dependent on etch parameters, chamber design and etch chemistry. Generally, chlorine based etch chemistry has a good etch rate selectivity to photoresist and can therefore be used to open a metal hard mask. It is, however, preferable to use a non-corrosive plasma (e.g., a fluorine plasma) to etch a metal hard mask since magnetic layers under the hard mask can be easily corroded by the chlorine plasma which is very reactive. On the other hand, non-corrosive fluorine plasma usually has poor etch rate selectivity to photoresist. According to an embodiment, a dual metal hard mask is used for patterning small tunneling junctions with optical lithography and reactive ion etching.

According to an embodiment, a dual hard mask is used for patterning small MTJs. According to an embodiment, a thin upper (top) hard mask is used to open a lower (bottom) hard mask using a photoresist barrier. According to an embodiment, the upper hard mask is thin enough to be etched with a photoresist barrier. The upper hard mask is then used as a barrier to etch the lower hard mask. If appropriate materials are chosen for the upper hard mask, it is possible to use a thin upper hard mask layer. The photoresist etch selectivity problem is not an issue if a thin upper hard mask layer is to be opened. According to an embodiment, a dual metal hard mask is used for the patterning of sub 100 nm MTJs by reactive ion etching.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A method of manufacturing an integrated circuit comprising a plurality of resistivity changing memory cells, the method comprising:
forming a stack of layers comprising a resistivity changing layer, a first conductive layer, a second conductive layer, and a masking layer which are stacked above each other in this order;
patterning the second conductive layer using the masking layer as a patterning mask;
patterning the first conductive layer using the second conductive layer as a patterning mask; and
patterning the resistivity changing layer using the first conductive layer as a patterning mask.

2. The method according to claim 1, wherein patterning the first conductive layer comprises using selective etching.

3. The method according to claim 2, wherein the selective etching of the first conductive layer comprises using a low-corrosive etching substance.

4. The method according to claim 3, wherein the low-corrosive etching substance comprises a fluorine plasma.

5. The method according to claim 3, wherein patterning the second conductive layer comprises using a corrosive etching substance.

6. The method according to claim 5, wherein the corrosive etching substance comprises a chlorine plasma.

7. The method according to claim 1, further comprising patterning the masking layer, wherein patterning the masking layer comprises:
providing a photo resist layer on the masking layer;
patterning the photo resist layer using a light exposure process; and
patterning the masking layer using the photo resist layer as a patterning mask.

8. The method according to claim 1, wherein the first conductive layer comprises TaN, WN, or a combination thereof.

9. The method according to claim 1, wherein the second conductive layer comprises NiFe, Ni, Pt, Pd, Cr, Ru, or a combination thereof.

10. The method according to claim 1, wherein the masking layer comprises dielectric material.

11. The method according to claim 1, wherein a ratio between a thickness of the first conductive layer and a thickness of the second conductive layer ranges between about 15 and about 30.

12. The method according to claim 11, wherein the thickness of the first conductive layer is about 1000 Å, and wherein the thickness of the second conductive layer is about 70 Å.

13. The method according to claim 12, wherein a thickness of the masking layer ranges between about 50 nm and about 200 nm.

14. The method according to claim 13, wherein a thickness of the resistivity changing layer is about 100 nm.

15. The method according to claim 1, wherein the patterned first conductive layer and the patterned second conductive layer together form at least one structure selected from a group of structures consisting of a memory cell contact; a memory cell electrode; and a composite structure comprising a memory cell contact; and a memory cell electrode.

16. The method according to claim 1, wherein each memory cell is a magneto-resistive memory cell, and wherein the resistivity changing layer is a magneto-resistive layer.

17. The method according to claim 1, wherein each memory cell is configured as a phase changing memory cell.

18. The method according to claim 1, wherein each memory cell is configured as a programmable metallization cell.

19. The method according to claim 1, wherein each memory cell is configured as a carbon memory cell.

20. A resistivity changing memory cell, comprising:
a stack of layers, the stack of layers comprising a resistivity changing layer, a first conductive layer, and a second conductive layer which are stacked above each other in this order,
wherein the first conductive layer and the second conductive layer together form at least one structure selected from the group consisting of a contact of the resistivity changing memory cell, an electrode of the resistivity changing memory cell, and a composite structure comprising a memory cell contact and a memory cell electrode, and
wherein a ratio between a thickness of the first conductive layer and a thickness of the second conductive layer ranges between about 15 and about 30.

21. The resistivity changing memory cell according to claim 20, wherein a material of the first conductive layer and a material of the second conductive layer are chosen such that the material of the first conductive layer is selectively etchable with respect to the material of the second conductive layer.

22. An integrated circuit comprising a resistivity changing memory cell, the resistivity changing memory cell comprising a stack of layers, the stack of layers comprising a resistivity changing layer, a first conductive layer, and a second conductive layer which are stacked above each other in this order,
wherein the first conductive layer and the second conductive layer together form at least one structure selected from a group of structures consisting of a contact of the memory cell, an electrode of the memory cell, or a composite structure comprising a memory cell contact and a memory cell electrode, and
wherein a ratio between a thickness of the first conductive layer and a thickness of the second conductive layer ranges between about 15 and about 30.

23. A memory module comprising at least one integrated circuit comprising at least one resistivity changing memory cell,
the at least one resistivity changing memory cell comprising a stack of layers, the stack of layers comprising a resistivity changing layer, a first conductive layer, and a second conductive layer which are stacked above each other in this order,
wherein a patterned first conductive layer and a patterned second conductive layer together form at least one structure selected from a group of structures consisting of a contact of the at least one resistivity changing memory cell memory cell, an electrode of at least one resistivity changing memory cell the memory cell, or a composite structure comprising a memory cell contact and a memory cell electrode, and
wherein a ratio between a thickness of the first conductive layer and a thickness of a second conductive layer ranges between about 15 and about 30.

24. The memory module according to claim 23, wherein the memory module is stackable.
